(19) United States
(12) Patent Application Publication
(10) Pub. No.: US 2020/0201086 A1
(43) Pub. Date: Jun. 25, 2020

(54) BONDING DEVICE FOR A DISPLAY PANEL AND BONDING METHOD FOR SAME

(71) Applicant: Wuhan China Star Optoelectronics Semiconductor Display Technology Co., Ltd., Wuhan Hubei (CN)

(72) Inventor: Dingwei ZHANG, Wuhan Hubei (CN)

(73) Assignee: Wuhan China Star Optoelectronics Semiconductor Display Technology Co., Ltd., Wuhan Hubei (CN)

(21) Appl. No.: 16/472,909

(22) PCT Filed: Mar. 20, 2019
(86) PCT No.: PCT/CN2019/078900

§ 371 Date: Jun. 24, 2019

(30) Foreign Application Priority Data
Dec. 19, 2018 (CN) 201811554561.0

(51) Int. Cl. G02F 1/13; H01L 51/56; B32B 37/12; B32B 38/18; H05K 3/36

(52) U.S. Cl. CPC G02F 1/1303; H01L 51/56; H05K 2203/0195; B32B 38/1858; H05K 3/361; B32B 37/1284

(57) ABSTRACT

A bonding device for a display panel and a bonding method for same are provided. The bonding device for the display panel includes a support platform and a carrier integrally disposed on the support platform. A first surface of the support platform and a first surface of the carrier are configured to carry the display panel and are positioned on a same horizontal plane.

### FIELD OF INVENTION

The present disclosure relates to the field of display technologies, and more particularly to a bonding device for a display panel and a bonding method for same.

### BACKGROUND OF INVENTION

Bonding is an important process in a current module process of organic light emitting display devices and liquid crystal displays. In a current bonding device for a display panel, a support platform and a carrier are independent mechanisms, and a current bonding process is as follows: a panel is placed on the support platform by a robot arm, and then the support platform is moved to a bonding area (directly above the carrier), then down to the carrier, a press head is lowered to press the panel. Because a height position of the support platform may change with an operation or a switch model, there are following risks during the operation:

1. Bonding of integrated circuit (IC): a height of the support platform is too low or too high (at a level of 100 μm), causing the panel to be suspended or lifted, and the panel may be damaged when the press head is pressed down.

2. Bonding of chip on film (COF), flexible printed circuit (FPC), or other flexible materials: due to flexibility requirements, current materials are getting thinner and easier to bend. If the height of the support platform is too low, and a bending of the FPC and the COF is severe (partially more than 1 cm), it may interfere with the carrier, causing the FPC and the COF to be unbonded. If the height of support platform is too high, a Y-direction offset of the bonding may occur.

Therefore, there is a need to provide a bonding device for a display panel and a bonding method for same to solve issues of the prior art.

### SUMMARY OF INVENTION

To solve the above technical problem, the present disclosure provides a bonding device for a display panel. The bonding device includes a support platform and a carrier integrally disposed on the support platform. A first surface of the support platform and a first surface of the carrier are configured to carry the display panel and are positioned on a same horizontal plane. A second surface of the carrier is disposed on a second surface of the support platform, and the second surface of the support platform is on a same horizontal surface as the second surface of the carrier. A distance between the first surface of the support platform and the second surface of the support platform is equal to a height of the carrier. Relative positions of the support platform and the carrier are fixed.

In an embodiment of the present disclosure, the bonding device further includes a press head disposed above the support platform and the carrier, a load bearing capacity of the support platform is greater than a pressing pressure of the press head, and a load bearing capacity of the carrier is greater than the pressing pressure of the press head.

In an embodiment of the present disclosure, the bonding device further includes a vacuum suction device disposed on one end of the carrier.

The present disclosure further provides a bonding device for a display panel. The bonding device includes a support platform and a carrier integrally disposed on the support platform. A first surface of the support platform and a first surface of the carrier are configured to carry the display panel and are positioned on a same horizontal plane.

In an embodiment of the present disclosure, a second surface of the carrier is disposed on a second surface of the support platform, and the second surface of the support platform is on a same horizontal surface as the second surface of the carrier.

In an embodiment of the present disclosure, a distance between the first surface of the support platform and the second surface of the support platform is equal to a height of the carrier.

In an embodiment of the present disclosure, relative positions of the support platform and the carrier are fixed.

In an embodiment of the present disclosure, the bonding device further includes a press head disposed above the support platform and the carrier.

In an embodiment of the present disclosure, a load bearing capacity of the support platform is greater than a pressing pressure of the press head.

In an embodiment of the present disclosure, a load bearing capacity of the carrier is greater than a pressing pressure of the press head.

In an embodiment of the present disclosure, the bonding device further includes a vacuum suction device disposed on one end of the carrier.

The present disclosure further provides a bonding method for a display panel including bonding the display panel using a bonding device for the display panel. The bonding device includes a support platform and a carrier integrally disposed on the support platform. A first surface of the support platform and a first surface of the carrier are configured to carry the display panel and are positioned on a same horizontal plane.

In an embodiment of the present disclosure, the method further includes placing the display panel on the first surface of the support platform and the first surface of the carrier, moving the carrier carrying the display panel directly below a press head, and pressing the display panel placed on the first surface of the carrier using the press head.

In an embodiment of the present disclosure, a second surface of the carrier is disposed on a second surface of the support platform, and the second surface of the support platform is on a same horizontal surface as the second surface of the carrier.

In an embodiment of the present disclosure, a distance between the first surface of the support platform and the second surface of the support platform is equal to a height of the carrier.

In an embodiment of the present disclosure, relative positions of the support platform and the carrier are fixed.

In an embodiment of the present disclosure, the bonding device further includes a press head disposed above the support platform and the carrier.

In an embodiment of the present disclosure, a load bearing capacity of the support platform is greater than a pressing pressure of the press head.

In an embodiment of the present disclosure, a load bearing capacity of the carrier is greater than a pressing pressure of the press head.

In an embodiment of the present disclosure, the bonding device further includes a vacuum suction device disposed on one end of the carrier.

Compared with the prior art, in order to solve the above technical problem, in the bonding device for the display panel and the bonding method for the display panel of the embodiment of the present disclosure, the carrier is integrally disposed on the support platform, and the first surface of the support platform and the first surface of the carrier are configured to carry the display panel and are positioned on the same horizontal plane, thereby simplifying a bonding of the bonding device, increasing a tact time, reducing a corresponding mechanism, and/or reducing cost.

### DESCRIPTION OF DRAWINGS

FIG. 1 is a schematic structural diagram of a bonding device for a display panel according to an embodiment of the present disclosure.

FIG. 2 is a schematic structural diagram of a bonding device for a display panel according to an embodiment of the present disclosure.

FIG. 3 is a schematic flowchart of a bonding method for a display panel according to an embodiment of the present disclosure.

### DETAILED DESCRIPTION OF PREFERRED EMBODIMENTS

The following description of the various embodiments is provided to illustrate the specific embodiments with reference to the accompanying drawings.

In order to make the above description of the present disclosure and other objects, features, and advantages of the present disclosure more comprehensible, preferred embodiments are described below, and are described in detail below with reference to the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

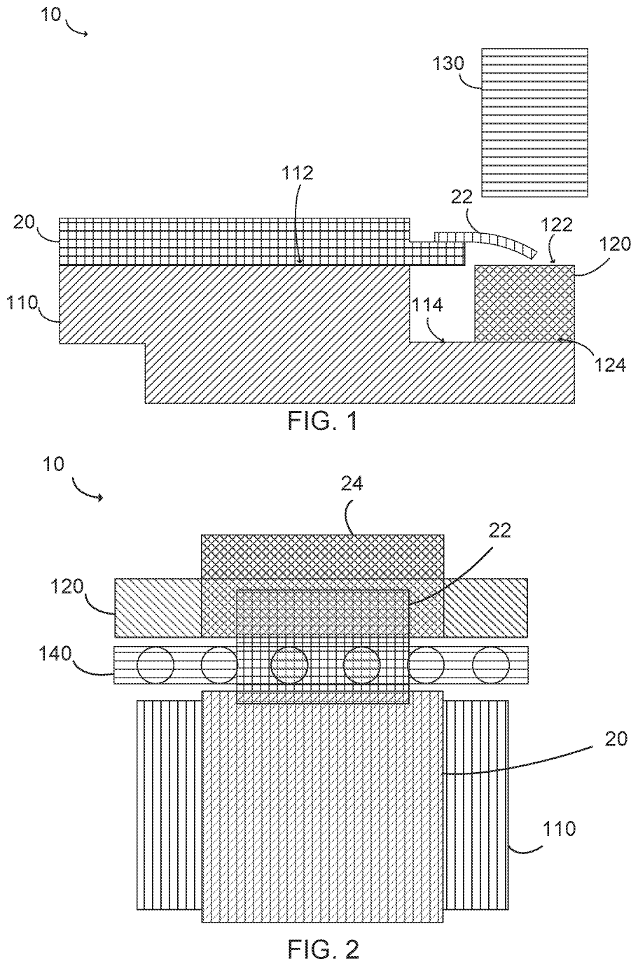

FIGS. 1 and 2 are schematic structural diagrams of a bonding device for a display panel according to an embodiment of the present disclosure.

Referring to FIGS. 1 and 2, a bonding device 10 of an exemplary embodiment of the present disclosure includes a support platform 110 and a carrier 120. The carrier 120 is integrally disposed on the support platform 110. A first surface 112 of the support platform 110 and a first surface 122 of the carrier 120 are configured to carry a display panel 20 and are positioned on a same horizontal plane. The embodiment of the present disclosure structurally integrates mechanisms of the support platform 110 and the carrier 120, thereby simplifying a bonding of the bonding device 10, increasing a tact time, reducing a corresponding mechanism, and/or reducing cost.

In details, a second surface 124 of the carrier 120 is disposed on a second surface 114 of the support platform 110, and the second surface 114 of the support platform 110 is on a same horizontal surface as the second surface 124 of the carrier 120. A distance between the first surface 112 of the support platform 110 and the second surface 112 of the support platform 110 is equal to a height of the carrier 120.

In details, mechanisms of the support platform 110 and the carrier 120 are integrated, that is, the carrier 120 is integrally disposed on the support platform 110, and relative positions of the support platform 110 and the carrier 120 are fixed. Therefore, before pressing the display panel 20, the display panel 20 can be moved and placed on the support platform 110 and the carrier 120 by a robot arm, thereby reducing a movement of the support platform to a position of the carrier, etc. in the prior art due to heights of the support platform 110 and the carrier 120 are mechanical, this does not change due to a switching model, and disadvantages of conventional designs are improved, and the embodiment of the present disclosure does not require the support platform 110 and the carrier 120 to be moved in a Z axis direction, such that a Z axis motor mechanism of the support platform 110 can be reduced, and cost of the bonding device 10 can be reduced.

The bonding device 10 of the exemplary embodiment of the present disclosure further includes a press head 130 and a vacuum suction device 140 (refer to FIG. 2). The press head 130 is disposed above the support platform 110 and the carrier 120.

In details, a load bearing capacity of the support platform 110 is greater than a pressing pressure of the press head 130. A load bearing capacity of the carrier 120 is greater than a pressing pressure of the press head 130. The vacuum suction device 140 is disposed on one end of the carrier 120, such as a front end of the carrier 120.

In details, a length of the support platform 110 is greater than a length of the carrier 120. A width of the support platform 110 is equal to a width of the carrier 120.

In an embodiment of the present disclosure, the support platform 110 and the carrier 120 are designed on a mechanism base, and relative positions of the support platform 110 and the carrier 120 are fixed. The support platform 110 and the carrier 120 do not move in the Z axis direction, and the support platform 110 and the carrier 120 are on the same horizontal surface. During operation, the display panel 20 is placed on the support platform 110 and the carrier 120, the mechanism base moves under the press head 130, and the press head 130 presses the display panel 20 to avoid interference abnormality due to a height difference between the support platform and the carrier in the prior art.

In details, in an embodiment of the present disclosure, in a mechanism manufacturing, it is necessary to ensure that the load bearing capacity of the support platform 110 and the carrier 120 is greater than the pressing pressure of the press head 130 (for example, within 1 KN). The support platform 110 is on the same horizontal plane as the carrier 120, and is periodically inspected (for example, monthly maintenance using a micrometer for measurement), and a position adjustment mechanism can be additionally added for subsequent position adjustment.

In details, in an embodiment of the present disclosure, the vacuum suction device 140 may be added to the front end of the carrier 120 to ensure an adhesive flatness of flexible materials such as a chip on film (COF) 22, a flexible printed circuit (FPC) 24, or other flexible materials of the display panel 20.

In the embodiment of the present disclosure, the support platform 110 and the carrier 120 are integrally designed, such that relative positions of the support platform 110 and the carrier 120 are fixed, and the operation is unified, which simplifies the bonding and is beneficial to reduce a risk of the bonding, increase a tact time, and reduce the cost of the mechanism.

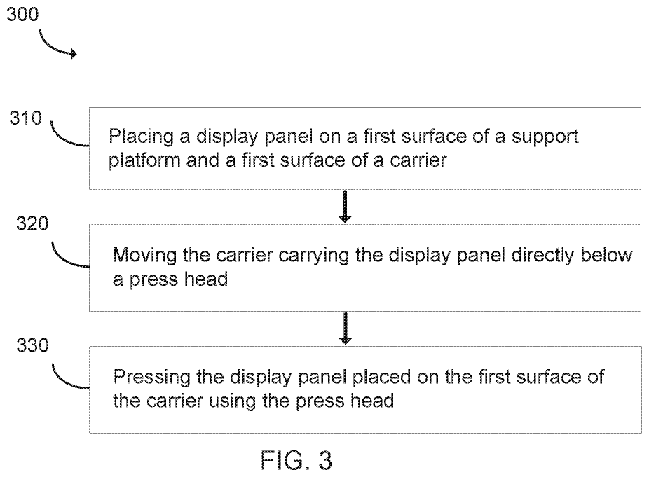

FIG. 3 is a schematic flowchart of a bonding method for a display panel according to an embodiment of the present disclosure.

A bonding method 300 for a display panel of the embodiment includes bonding the display panel 20 using the bonding device 10.

In an embodiment of the present disclosure, the bonding method 300 further includes: at a block 310, placing the display panel 20 on the first surface 112 of the support platform 110 and the first surface 122 of the carrier 120, at a block 320, moving the carrier 120 carrying the display panel 20 directly below the press head 130, and at a block 330, pressing the display panel 20 placed on the first surface 122 of the carrier 120 using the press head 130.

In details, mechanisms of the support platform 110 and the carrier 120 are integrated, that is, the carrier 120 is integrally disposed on the support platform 110, and relative positions of the support platform 110 and the carrier 120 are fixed. Therefore, before pressing the display panel 20, the display panel 20 can be moved and placed on the support platform 110 and the carrier 120 by a robot arm, thereby reducing a movement of the support platform to a position of the carrier, etc. in the prior art due to heights of the support platform 110 and the carrier 120 are mechanical, this does not change due to a switching model, and disadvantages of conventional designs are improved, and the embodiment of the present disclosure does not require the support platform 110 and the carrier 120 to be moved in a Z axis direction, such that a Z axis motor mechanism of the support platform 110 can be reduced, and cost of the bonding device 10 can be reduced.

In the bonding device for the display panel and the bonding method for the display panel of the embodiment of the present disclosure, the carrier is integrally disposed on the support platform, and the first surface of the support platform and the first surface of the carrier are configured to carry the display panel and are positioned on the same horizontal plane, thereby simplifying a bonding of the bonding device, increasing a tact time, reducing a corresponding mechanism, and/or reducing cost.

Although the present disclosure is described via one or more embodiments, those of ordinary skill in the art can come up with equivalent variations and modifications based upon the understanding of the specification and the accompanying drawings. The present disclosure includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

What is claimed is:

1. A bonding device for a display panel, comprising:
a support platform; and
a carrier integrally disposed on the support platform;
wherein a first surface of the support platform and a first surface of the carrier are configured to carry the display panel and are positioned on a same horizontal plane;
wherein a second surface of the carrier is disposed on a second surface of the support platform, and the second surface of the support platform is on a same horizontal surface as the second surface of the carrier;
wherein a distance between the first surface of the support platform and the second surface of the support platform is equal to a height of the carrier; and
wherein relative positions of the support platform and the carrier are fixed.

2. The bonding device for the display panel according to claim 1, further comprising a press head disposed above the support platform and the carrier, wherein a load bearing capacity of the support platform is greater than a pressing pressure of the press head, and a load bearing capacity of the carrier is greater than the pressing pressure of the press head.

3. The bonding device for the display panel according to claim 1, further comprising a vacuum suction device disposed on one end of the carrier.

4. A bonding device for a display panel, comprising:
a support platform; and
a carrier integrally disposed on the support platform;
wherein a first surface of the support platform and a first surface of the carrier are configured to carry the display panel and are positioned on a same horizontal plane.

5. The bonding device for the display panel according to claim 4, wherein a second surface of the carrier is disposed on a second surface of the support platform, and the second surface of the support platform is on a same horizontal surface as the second surface of the carrier.

6. The bonding device for the display panel according to claim 5, wherein a distance between the first surface of the support platform and the second surface of the support platform is equal to a height of the carrier.

7. The bonding device for the display panel according to claim 4, wherein relative positions of the support platform and the carrier are fixed.

8. The bonding device for the display panel according to claim 4, further comprising a press head disposed above the support platform and the carrier.

9. The bonding device for the display panel according to claim 8, wherein a load bearing capacity of the support platform is greater than a pressing pressure of the press head.

10. The bonding device for the display panel according to claim 8, wherein a load bearing capacity of the carrier is greater than a pressing pressure of the press head.

11. The bonding device for the display panel according to claim 4, further comprising a vacuum suction device disposed on one end of the carrier.

12. A bonding method for a display panel, comprising:
bonding the display panel using a bonding device for the display panel;
wherein the bonding device comprises:
a support platform; and
a carrier integrally disposed on the support platform;
wherein a first surface of the support platform and a first surface of the carrier are configured to carry the display panel and are positioned on a same horizontal plane.

13. The method according to claim 12, further comprising:
placing the display panel on the first surface of the support platform and the first surface of the carrier;
moving the carrier carrying the display panel directly below a press head; and
pressing the display panel placed on the first surface of the carrier using the press head.

14. The method according to claim 12, wherein a second surface of the carrier is disposed on a second surface of the support platform, and the second surface of the support platform is on a same horizontal surface as the second surface of the carrier.

15. The method according to claim 14, wherein a distance between the first surface of the support platform and the second surface of the support platform is equal to a height of the carrier.

16. The method according to claim 12, wherein relative positions of the support platform and the carrier are fixed.

17. The method according to claim 12, the bonding device further comprises a press head disposed above the support platform and the carrier.

18. The method according to claim 17, wherein a load bearing capacity of the support platform is greater than a pressing pressure of the press head.

19. The method according to claim 17, wherein a load bearing capacity of the carrier is greater than a pressing pressure of the press head.

20. The method according to claim 12, wherein the bonding device further comprises a vacuum suction device disposed on one end of the carrier.
